(19) United States
(12) Patent Application Publication
(10) Pub. No.: US 2025/0344530 A1
(43) Pub. Date: Nov. 6, 2025

(54) PIXEL ARRAY OF IMAGE SENSOR AND IMAGE SENSOR

(71) Applicant: MAGVISION SEMICONDUCTOR (BEIJING) INC, Beijing (CN)

(72) Inventor: Kaiyuan WU, Beijing (CN)

(21) Appl. No.: 19/198,412

(22) Filed: May 5, 2025

(30) Foreign Application Priority Data
May 6, 2024 (CN) 202410548813.8

(51) Int. Cl. H10F 39/00; H10F 39/18

(52) U.S. Cl. CPC H10F 39/8023; H10F 39/182; H10F 39/8053; H10F 39/8063

(57) ABSTRACT

The present invention provides a pixel array of an image sensor and an image sensor. The pixel array includes: pixel units regularly arranged in row-wise and column-wise directions, which includes image pixel units and phase pixel units; and microlenses provided on pixel units so as to be each commonly shared by image pixel units, or by an equal plurality of phase pixel units, which make up first or second phase-pixel unit tuple. The first and second phase-pixel unit tuples are in different rows and in same columns, and are paired into phase-pixel unit tuple pairs to be detected for phase differences. The use of identical microlenses is allowed, and no missing of pixel unit values occurs in regions of the phase pixel units, resulting in improved image quality of the image sensor and dispensing with the need for PDC. The phase pixel units do not require any additional readout times.

### CROSS-REFERENCES TO RELATED APPLICATION

This application claims the priority of Chinese patent application number 202410548813.8, filed on May 6, 2024, the entire contents of which are incorporated herein by reference.

### TECHNICAL FIELD

The present invention relates to the field of image sensor technology and, in particular, to Pixel Array of an image sensor and an image sensor.

### BACKGROUND

Complementary metal-oxide-semiconductor (CMOS) image sensors are CMOS-based solid-state sensing devices. Compared with charge-coupled device (CCD) image sensors, CMOS image sensors are manufactured at lower cost and consume less power. Therefore, CMOS image sensors are widely used in various electronic devices including portable devices such as smart phones and digital cameras.

In CMOS image sensors, in order to enable each pixel to receive as much light exiting a lens as possible, a microlens is provided on top of the pixel to converge light. This can avoid a waste of light, increase light utilization and improve image quality. Such microlenses are known as on-chip lenses (OCLs).

Microlens phase detection (MLPD) is an autofocus technique based on phase difference detection and analysis of light received by an array of microlenses on respective pixels in a CMOS image sensor. This technique allows for faster focusing and better performance even in low-light conditions.

Most small-pixel CMOS image sensors currently available on the market employ a 2×2 MLPD, 1×1 OCL Pixel Array design, as shown in FIG. 1. Referring to FIG. 1, Pixel Array contains a plurality of pixel units 10 regularly arranged in row-wise and column-wise directions, and microlenses 20 are provided on top of the pixel units 10. The pixel units 10 include image pixel units 11 for collecting image information and phase pixel units 12 for collecting phase information necessary for focusing. Each image pixel unit 11 is provided with one microlens 20, and every four adjacent (2×2) phase pixel units 12 share a common microlens 20. For this reason, this design is termed “2×2 MLPD, 1×1 OCL” (“MLPD” indicates the microlenses used for phase detection and focusing, while “OCL” indicates the regular microlenses used for imaging).

Although 1×1 OCL design provides better imaging in non-MLPD regions (regions without MLPD, e.g., other regions than the region 30 of FIG. 1) in a full-size mode than 2×2 OCL designs, quad sensitivity correction (QSC) and linear compensation are still necessary for small pixels. Moreover, 1×1 OCL design is associated with a number of other disadvantages. For example, each MLPD region (e.g., the region 30 of FIG. 1) leads to missing of values from 4 pixels and hence a degradation of imaging quality, necessitating PD pixel correction (PDC) for compensating for the missing and surrounding pixels. As a second example, sensitivity and quantum efficiency are both low in the 4C binning mode, possibly leading to a SNR10 (Signal-to-Noise Ratio) degradation of approximately 7%. As a third example, both PDC and PD pixel fix (PDF) are needed, possibly leading to expansion of chip size.

FIG. 2 shows a schematic illustration of a 2×2 MLPD, 2×2 OCL Pixel Array. Referring to FIG. 2, every 2×2 image pixel unit 11 shares a common microlens 20, and so do every 2×2 phase pixel unit 12. The 2×2 MLPD, 2×2 OCL Pixel Array has comparable performance to 2×2 MLPD, 1×1 OCL Pixel Array at MLPD regions (e.g., the region 30 of FIG. 2) and is associated with similar disadvantages.

### SUMMARY

It is an object of the present invention to provide a pixel array of an image sensor and an image sensor, in which no missing of pixel values occurs in phase-pixel unit regions, resulting in improved image quality of the image sensor and dispensing with the need for PDC.

To this end, in a first aspect of the present invention, there is provided a pixel array of an image sensor, which includes:
a plurality of pixel units regularly arranged in row-wise and column-wise directions, the pixel units including image pixel units for collecting image information and phase pixel units for collecting phase information necessary for focusing; and
microlenses provided on the pixel units so as to be each commonly shared by a plurality of image pixel units, or by an equal plurality of phase pixel units, which make up a first phase-pixel unit tuple or a second phase-pixel unit tuple; wherein the first phase-pixel unit tuples are in different rows from, and in the same columns as, the second phase-pixel unit tuples, and wherein the first phase-pixel unit tuples and the second phase-pixel unit tuples are paired into phase-pixel unit tuple pairs to be detected for phase differences.

Optionally, each microlens may be commonly shared by 2×2 image pixel units, or by 2×2 phase pixel units.

Optionally, two phase pixel units of a first or second column in each first phase- pixel unit tuple may be adapted for phase detection, wherein two phase pixel units of a second or first column in each second phase-pixel unit tuple are adapted for phase detection.

Optionally, color filters may be provided between the pixel units and the microlenses, wherein for each color, one color filter is commonly shared by 2×2 pixel units, which also commonly share one microlens.

Optionally, when readout is conducted on every 2×2 pixel units that commonly share one microlens while treating them as one single pixel, the two phase pixel units of the first column in each first phase-pixel unit tuple may be applied with TX control signals different from those applied to image pixel units in the same row, and the two phase pixel units of the second column in each second phase-pixel unit tuple may be applied with TX control signals different from those applied to image pixel units in the same row.

Optionally, when readout is conducted on every single pixel, the two phase pixel units of the first column in each first phase-pixel unit tuple may be applied with the same TX control signals as image pixel units in the same row, and the two phase pixel units of the second column in each second phase-pixel unit tuple may be applied with the same TX control signals as image pixel units in the same row.

Optionally, the phase-pixel unit tuple pairs may be spaced apart in the column-wise direction and the phase-pixel unit tuples may be spaced apart in the row-wise direction.

Optionally, the pixel array may include a plurality of repetitive units repeatedly arranged in the row-wise and column-wise directions, wherein in each repetitive unit, phase-pixel unit tuples in adjacent columns are in different rows.

Optionally, the pixel array may include a plurality of repetitive units repeatedly arranged in the row-wise and column-wise directions, wherein in each repetitive unit, phase-pixel unit tuple pairs in adjacent rows are in different columns.

To the above end, in a second aspect of the present invention, there is provided an image sensor including the pixel array as defined above.

In summary, in Pixel Array and image sensor of the present invention, each microlens is commonly shared by a plurality of image pixel units, or by an equal plurality of phase pixel units, which make up a first phase-pixel unit tuple or a second phase-pixel unit tuple. The first phase-pixel unit tuples are in different rows from, and in the same columns as, the second phase-pixel unit tuples. Moreover, the first phase-pixel unit tuples and the second phase-pixel unit tuples are paired into phase-pixel unit tuple pairs to be detected for phase differences. With this arrangement, since each microlens is commonly shared by a number of phase pixel units, or by the same number of image pixel units, the use of identical microlenses for all the pixel units is allowed, and no missing of pixel values occurs in regions of the phase pixel units, resulting in improved image quality of the image sensor and dispensing with the need for PDC. Further, as the first phase-pixel unit tuples are arranged in different rows from the second phase-pixel unit tuples, readout can be accomplished without any separate readout timing scheme, dispensing out the need for additional readout times.

Furthermore, in the 4C binning mode, only PDF is necessary, allowing shrinkage of chip size.

### BRIEF DESCRIPTION OF THE DRAWINGS

FIG. 1 shows a schematic illustration of a 2×2 MLPD, 1×1 OCL Pixel Array.

FIG. 2 shows a schematic illustration of a 2×2 MLPD, 2×2 OCL Pixel Array.

FIG. 3 schematically illustrates Pixel Array of an image sensor according to an embodiment of the present invention.

FIG. 4 schematically illustrates a distribution of TX control signals applied to Pixel Array of an image sensor according to an embodiment of the present invention.

FIG. 5 schematically illustrates a distribution of phase pixel units in an image sensor according to an embodiment of the present invention.

FIG. 6 schematically illustrates a distribution of phase pixel units in an image sensor according to another embodiment of the present invention.

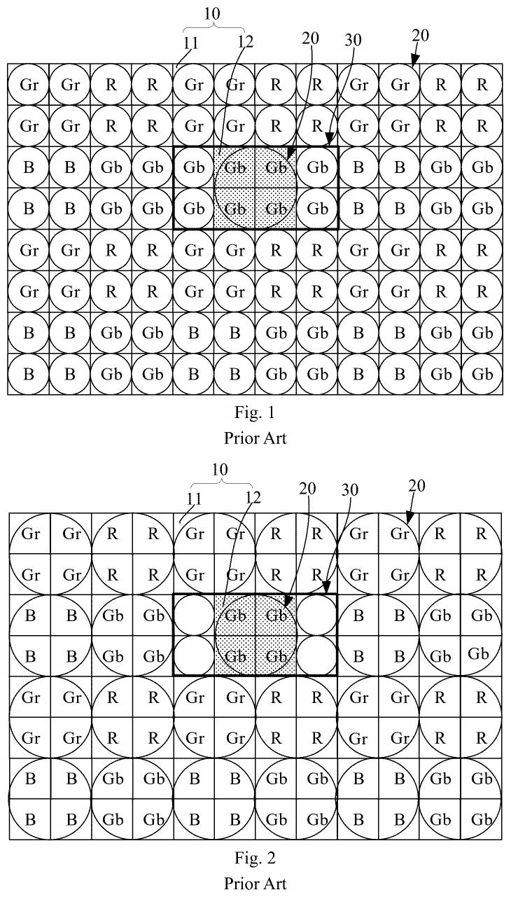

### DETAILED DESCRIPTION

Objects, advantages and features of the present invention will become more apparent upon reading the following more detailed description with reference to the accompanying drawings, which illustrate particular embodiments thereof. Note that the figures are provided in a very simplified form not necessarily drawn to exact scale for the only purpose of helping to explain the disclosed embodiments in a more convenient and clearer way. In addition, the illustrated structures are usually part of their real-world counterparts. In particular, as the figures tend to have distinct emphases, they are sometimes drawn to different scales.

As used herein, the singular forms “a”, “an” and “the” include plural referents, unless the context clearly dictates otherwise. As used herein, the term “or” is generally employed in the sense of “and/or”, unless the context clearly dictates otherwise. As used herein, the term “a number of” is generally employed in the sense of “at least one”, unless the context clearly dictates otherwise. As used herein, the term “at least two” is generally employed in the sense of “two or more”, unless the context clearly dictates otherwise. In addition, the terms “first”, “second” and “third” are intended only for illustration and are not to be construed as denoting or implying relative importance, or as implicitly indicating the number of the referenced items. Accordingly, defining an item with “first”, “second” or “third” is an explicit or implicit indication of the presence of one or at least two such items, unless the context clearly dictates otherwise.

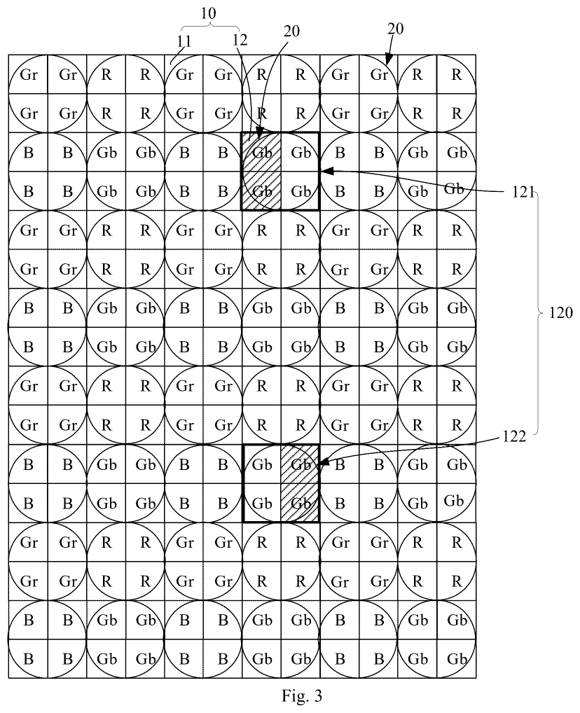

FIG. 3 schematically illustrates Pixel Array of an image sensor according to an embodiment of the present invention. Referring to FIG. 3, Pixel Array includes:
a plurality of pixel units 10 regularly arranged in row-wise and column-wise directions, the pixel units 10 including image pixel units 11 for collecting image information and phase pixel units 12 for collecting phase information necessary for focusing; and
microlenses 20 provided on the pixel units 10, each microlens 20 is commonly shared by a plurality of image pixel units 11, or by an equal plurality of phase pixel units 12, the plurality of phase pixel units 12 sharing a common microlens 20 make up a first phase-pixel unit tuple 121 or a second phase-pixel unit tuple 122, wherein the first phase-pixel unit tuples 121 are in different rows from, and in the same columns as, the second phase-pixel unit tuples 122, and wherein the first phase-pixel unit tuples 121 and the second phase-pixel unit tuples 122 are paired into phase-pixel unit tuple pairs 120 to be detected for phase differences.

As each microlens 20 is commonly shared by an equal plurality of pixel units 10, the use of identical microlenses 20 is allowed, and no missing of pixel values occurs at regions of the phase pixel units 12, resulting in better image quality of the image sensor and dispensing with the need for PD pixel correction (PDC).

In one embodiment of the present invention, each microlens 20 is commonly shared by 2×2 image pixel units 11, or by 2×2 phase pixel units 12. That is, Pixel Array of the image sensor is of a 2×2 MLPD, 2×2 OCL design. Of course, the present invention is not so limited.

In one embodiment of the present invention, color filters are provided between the pixel units 10 and the microlens 20 to enable the pixel units 10 to display different colors. In the illustrated embodiment, for each color, one color filter is commonly shared by 2×2 pixel units 10, which also commonly share one microlens 20. Referring to FIG. 3, every 2×2 pixel units 10 display the same color and commonly share one microlens 20. In the illustrated embodiment, the pixel units 10 can display four colors, namely, R, Gr, Gb and B. Gr and R alternate in one row, and B and Gb in the next row, and the two rows are repeated. In the illustrated embodiment, the phase pixel units 12 are Gb pixel units 10, but the present invention is not so limited.

In one embodiment of the present invention, phases of two phase pixel units 12 of a first column in each first phase-pixel unit tuple 121 and two phase pixel units 12 of a second column in each second phase-pixel unit tuple 122 are detected. Autofocus is accomplished based on phase differences between the first phase-pixel unit tuples 121 and the second phase-pixel unit tuples 122. Since the first phase-pixel unit tuples 121 are in different rows from, and in the same columns as, the second phase-pixel unit tuples 122, readout can be accomplished without any separate readout timing scheme, dispensing out the need for additional readout times. It will be understood that, in alternative embodiments of the present invention, phases of two phase pixel units 12 of a second column in each first phase-pixel unit tuple 121 and two phase pixel units 12 of a first column in each second phase-pixel unit tuple 122 may be detected. In further alternative embodiments of the present invention, phases of two phase pixel units 12 of a first row in each first phase-pixel unit tuple 121 and two phase pixel units 12 of a second row in each second phase-pixel unit tuple 122 may be detected. In these cases, autofocus can be still achieved based on phase differences between the first phase-pixel unit tuples 121 and the second phase-pixel unit tuples 122. The present invention is not limited in this regard.

In one embodiment of the present invention, when readout is conducted on every 2×2 pixel units 10 that commonly share a single microlens while treating them as one single pixel, i.e., in the 4C binning mode, the two phase pixel units 12 of the first column in each first phase-pixel unit tuple 121 are applied with TX control signals different from those applied to the image pixel units 11 in the same row, and the two phase pixel units 12 of the second column in each second phase-pixel unit tuple 122 are also applied with TX control signals different from those applied to the image pixel units 11 in the same row.

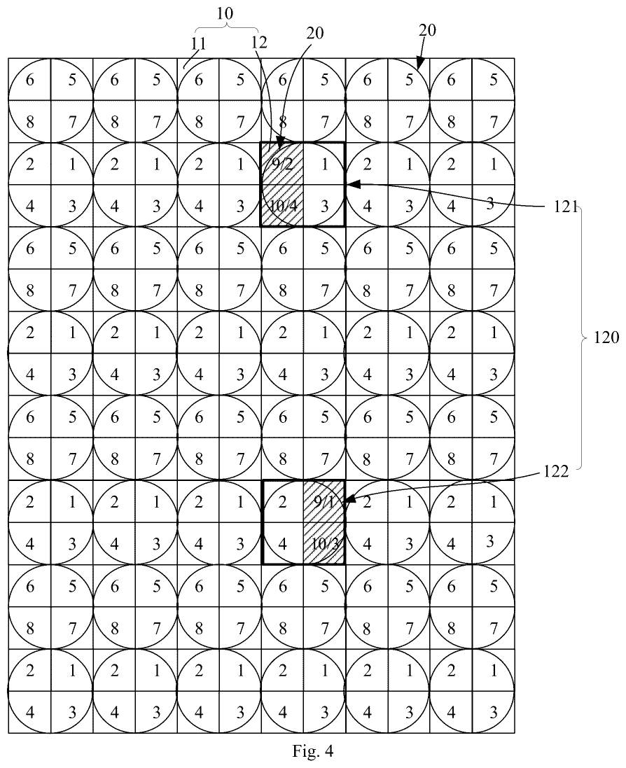

FIG. 4 schematically illustrates a distribution of TX control signals applied to Pixel Array according to an embodiment of the present invention. Referring to FIGS. 3 to 4, in the 4C binning mode, in each row of Gb and B image pixel units 11, TX control signals 1, 2, 3, 4 are applied to the respective four image pixel units 11 in each Gb tuple and in each B tuple. Moreover, in each row of R and Gr image pixel units 11, TX control signals 5, 6, 7, 8 are applied to the respective four image pixel units 11 in each R tuple and in each Gr tuple. In contrast, in each first phase-pixel unit tuple 121, the left two phase pixel units 12 are applied with respective TX control signals 9, 10, which are different from the TX control signals applied to the image pixel units 11 in the same row, and the right two phase pixel units 12 are applied with the respective TX control signals 1, 3 that are applied to the image pixel units 11 in the same row. Moreover, in each second phase-pixel unit tuple 122, the left two phase pixel units 12 are applied with the respective TX control signals 2, 4 that are applied to the image pixel units 11 in the same row, and the right two phase pixel units 12 are applied with the respective TX control signals 9, 10, which are different from the TX control signals applied to the image pixel units 11 in the same row.

In one embodiment of the present invention, when readout is conducted on every single pixel 10, for example, in a full-size mode, the two phase pixel units 12 of the first column in each first phase-pixel unit tuple 121 are applied with the same TX control signals as the image pixel units 11 in the same row, and the two phase pixel units 12 of the second column in each second phase-pixel unit tuple 122 are also applied with the same TX control signals as the image pixel units 11 in the same row.

Referring to FIGS. 3 and 4, in the full-size mode, in each row of Gb and B image pixel units 11, TX control signals 1, 2, 3, 4 are applied to the respective four image pixel units 11 in each Gb tuple and in each B tuple. Moreover, in each row of R and Gr image pixel units 11, TX control signals 5, 6, 7, 8 are applied to the respective four image pixel units 11 in each R tuple and in each Gr tuple. Additionally, in each first phase-pixel unit tuple 121, the left two phase pixel units 12 are applied with the TX control signals 2, 4, which are also applied to the image pixel units 11 in the same row, and the right two phase pixel units 12 are applied with the TX control signals 1, 3, which are also applied to the image pixel units 11 in the same row. Further, in each second phase-pixel unit tuple 122, the left two phase pixel units 12 are applied with the TX control signals 2, 4, which are also applied to the image pixel units 11 in the same row, and the right two phase pixel units 12 are applied with the TX control signals 1, 3, which are also applied to the image pixel units 11 in the same row.

Therefore, Pixel Array of the present invention supports operation in both the 4C binning and full-size modes, without any separate readout timing scheme. Further, in the 4C binning mode, it only needs PD pixel unit fix (PDF), resulting in shrinkage of chip size.

In one embodiment of the present invention, the phase-pixel unit tuple pairs 120 are spaced apart in the column-wise direction, and the phase-pixel unit tuples are spaced apart in the row-wise direction. For example, in the column-wise direction, a first phase-pixel unit tuple 121 is spaced apart from an immediately downstream second phase-pixel unit tuple 122 and paired therewith into a phase-pixel unit tuple pair 120; another first phase-pixel unit tuple 121 is immediately downstream of and equally spaced apart from the second phase-pixel unit tuple 122, and another second phase-pixel unit tuple 122 is immediately downstream of and equally spaced apart from the other first phase-pixel unit tuple 121 and paired therewith into another phase-pixel unit tuple pair 120; and so forth. Alternatively, in the column-wise direction, a first phase-pixel unit tuple 121 is spaced apart from an immediately downstream second phase-pixel unit tuple 122 and paired therewith into a phase-pixel unit tuple pair 120; another second phase-pixel unit tuple 122 is immediately downstream of and equally spaced apart from the second phase-pixel unit tuple 122, and another first phase-pixel unit tuple 121 is immediately downstream of and equally spaced apart from the other second phase-pixel unit tuple 122 and paired therewith into another phase-pixel unit tuple pair 120; a third first phase-pixel unit tuple 121 is immediately downstream of and equally spaced apart from the other first phase-pixel unit tuple 121, and a third second phase-pixel unit tuple 122 is immediately downstream of and equally spaced apart from the third first phase-pixel unit tuple 121 and paired therewith into a third phase-pixel unit tuple pair 120; and so forth.

In the row-wise direction, the first phase-pixel unit tuple 121 are spaced apart, and the second phase-pixel unit tuples 122 are also spaced apart, but in different rows.

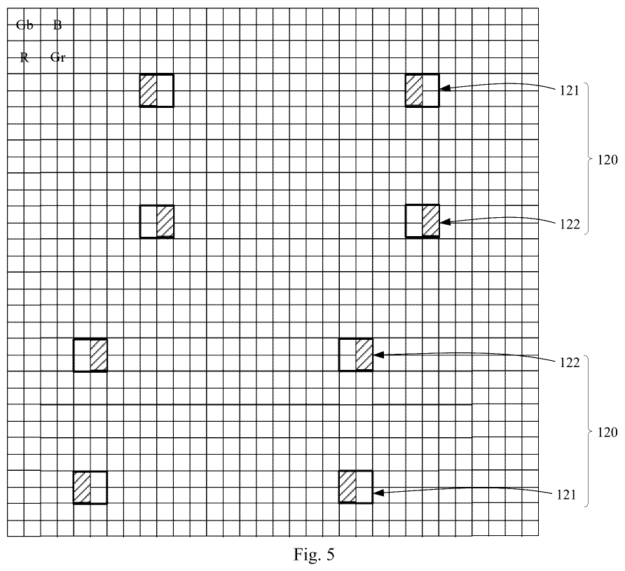

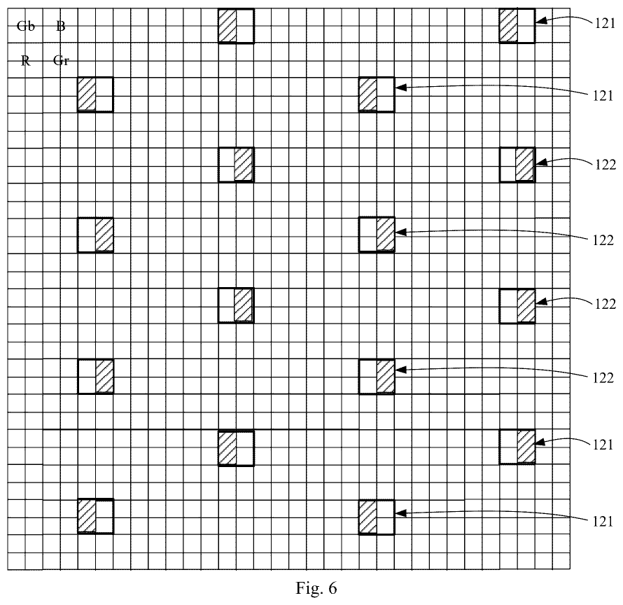

FIG. 5 schematically illustrates a distribution of the phase pixel units in Pixel Array according to an embodiment of the present invention. FIG. 6 schematically illustrates a distribution of the phase pixel units in Pixel Array according to another embodiment of the present invention. In Pixel Array, the pixel units regularly arranged in the row-wise and column-wise directions make up a plurality of repetitive units, which are repeatedly arranged in the row-wise and column-wise directions. FIGS. 5 and 6 each depict one such repetitive unit.

In one embodiment of the present invention, in each repetitive unit, phase-pixel unit tuple pairs in adjacent rows are in different columns. In FIG. 5, a first row contains first phase-pixel unit tuples 121, and a second row contains second phase-pixel unit tuples 122. The first phase-pixel unit tuples 121 of the first row and the second phase- pixel unit tuples 122 of the second row together make up a row of phase-pixel unit tuple pair 120 (denoted as “Row 1”). Additionally, a third row contains second phase-pixel unit tuples 122, and a fourth row contains first phase-pixel unit tuples 121. The second phase-pixel unit tuples 122 of the third row and the first phase-pixel unit tuples 121 of the fourth row together make up another row of phase-pixel unit tuple pairs 120 (“Row 2”). The two rows of phase-pixel unit tuple pairs 120 are adjacent rows, and are in different columns. The phase-pixel unit tuple pairs 120 in Row 2 are shifted to the left or right (to the right, as shown, as an example) by 2 pixel units, compared to those of Row 1 (notably, in the illustrated embodiment, every 4 pixel units are treated as one single pixel).

TABLE 1

| 2 × 2 OCL | PD | Missing Pixels |
|---|---|---|
| Full-Size Mode | <25% | 0% |
| 4C Binning Mode | 8/256 = 3% | 8/256 = 3% |

Table 1 presents a (phase) pixel unit density (PD) and missing pixel comparison between the different modes of Pixel Array of FIG. 5. As can be seen from Table 1, there are no missing pixels in the full-size mode, and the percentage of missing pixels in the 4C binning mode is as low as 3%. Therefore, better imaging can be obtained in phase-pixel unit regions, and PDC is not necessary.

In one embodiment of the present invention, in each repetitive unit, phase-pixel units in adjacent columns are in different rows. In FIG. 6, there are 4 columns containing phase-pixel unit tuples. In each adjacent pair of columns, e.g., Column 1 and Column 2, the phase-pixel unit tuples in Column 2 are in different rows from those in Column 1. The phase-pixel units in Column 2 are shifted upwards by 2 pixel units, compared to those of Column 1 (notably, in the illustrated embodiment, every 4 pixel units are also treated as one single pixel). In this way, the phase pixel units are arranged in a staggered manner in Pixel Array. Of course, it is also possible that the phase-pixel units in Column 2 are shifted upwards by one pixel unit compared to those of Column 1, with the phase-pixel units in Column 3 being in turn shifted upwards by one pixel unit compared to those of Column 2. Of course, the locations of the phase pixel units are not so limited.

TABLE 2

| 2 × 2 OCL | PD | Missing pixels |
|---|---|---|
| Full-Size Mode | ≤25% | 0% |
| 4C Binning Mode | 16/256 = 6% | 16/256 = 6% |

Table 2 presents a PD and missing pixel comparison between the different modes of Pixel Array of FIG. 6. As can be seen from Table 2, there are no missing pixels in the full-size mode, and the percentage of missing pixels in the 4C binning mode is as low as 6%. Therefore, better imaging can be obtained in phase-pixel unit regions, and PDC is not necessary.

In the two embodiments of FIGS. 5 and 6, phase-pixel unit tuple pairs adjacent in the column-wise direction are relatively shifted in the row-wise direction in one embodiment, and phase-pixel unit tuples adjacent in the row-wise direction are relatively shifted in the column-wise direction in the other embodiment. In other embodiments, the phase-pixel unit tuples may also be arranged in other manners known to those skilled in the art, and the present invention is not limited to any particular arrangement.

In Pixel Array of the present invention, each microlens 20 is commonly shared by a plurality of image pixel units 11, or by an equal plurality of phase pixel units 12, which make up a first phase-pixel unit tuple 121 or a second phase-pixel unit tuple 122. The first phase-pixel unit tuples 121 are in different rows from, and in the same columns as, the second phase-pixel unit tuples 122. Moreover, the first phase-pixel unit tuples 121 and the second phase-pixel unit tuples 122 are paired into phase-pixel unit tuple pairs 120 to be detected for phase differences. With this arrangement, since each microlens 20 is commonly shared a number of phase pixel units 12, or by the same number of image pixel units 11, the use of identical microlenses 20 for all the pixel units 10 is allowed, and no missing of pixel values occurs in regions of the phase pixel units 12, resulting in improved image quality of the image sensor and dispensing with the need for PDC. Further, as the first phase-pixel unit tuples 121 are arranged in different rows from the second phase-pixel unit tuples 122, readout can be accomplished without any separate readout timing scheme, dispensing out the need for additional readout times.

Furthermore, in the 4C binning mode, only PDF is necessary, allowing shrinkage of chip size.

The present invention also provides an image sensor including Pixel Array as discussed above.

In summary, the present invention provides Pixel Array of an image sensor and an image sensor, in which each microlens is commonly shared by a plurality of image pixel units, or by an equal plurality of phase pixel units, which make up a first phase-pixel unit tuple or a second phase-pixel unit tuple. The first phase-pixel unit tuples are in different rows from, and in the same columns as, the second phase-pixel unit tuples. Moreover, the first phase-pixel unit tuples and the second phase-pixel unit tuples are paired into phase-pixel unit tuple pairs to be detected for phase differences. With this arrangement, since each microlens is commonly shared by a number of phase pixel units, or by the same number of image pixel units, the use of identical microlenses for all the pixel units is allowed, and no missing of pixel values occurs in regions of the phase pixel units, resulting in improved image quality of the image sensor and dispensing with the need for PDC. Further, as the first phase-pixel unit tuples are arranged in different rows from the second phase-pixel unit tuples, readout can be accomplished without any separate readout timing scheme, dispensing out the need for additional readout times.

Furthermore, in the 4C binning mode, only PDF is necessary, allowing shrinkage of chip size.

The description presented above is merely that of a few preferred embodiments of the present invention and does not limit the scope thereof in any sense. Any and all changes and modifications made by those of ordinary skill in the art based on the above teachings fall within the scope as defined in the appended claims.

What is claimed is:

1. A pixel array of an image sensor, comprising:
a plurality of pixel units regularly arranged in a row-wise direction and a column-wise direction, the plurality of pixel units including image pixel units and phase pixel units, the image pixel units for collecting image information and the phase pixel units for collecting phase information necessary for focusing; and
microlenses provided on the plurality of pixel units, a plurality of image pixel units sharing one of the microlenses, a plurality of phase pixel units sharing another one of the microlenses, each microlens commonly shared by an equal plurality of pixel units, wherein the plurality of phase pixel units sharing the common microlens make up a first phase-pixel unit tuple or a second phase-pixel unit tuple; wherein the first phase-pixel unit tuples are in different rows from, and in the same columns as, the second phase-pixel unit tuples, and wherein the first phase-pixel unit tuples and the second phase-pixel unit tuples are paired into phase-pixel unit tuple pairs to be detected for phase differences.

2. The pixel array according to claim 1, wherein 2×2 image pixel units share one of the microlenses, and wherein 2×2 phase pixel units share another one of the microlenses.

3. The pixel array according to claim 2, wherein two phase pixel units of a first or second column in each first phase-pixel unit tuple are adapted for phase detection, wherein two phase pixel units of a second or first column in each second phase-pixel unit tuple are adapted for phase detection.

4. The pixel array according to claim 3, wherein color filters are provided between the pixel units and the microlenses, wherein for each color, one color filter is commonly shared by 2×2 pixel units, which also commonly share one microlens.

5. The pixel array according to claim 4, wherein when readout is conducted on every 2×2 pixel units that commonly share one microlens while treating them as one single pixel, the two phase pixel units of the first column in each first phase-pixel unit tuple are applied with TX control signals different from those applied to image pixel units in the same row, and the two phase pixel units of the second column in each second phase-pixel unit tuple are applied with TX control signals different from those applied to image pixel units in the same row.

6. The pixel array according to claim 4, wherein when readout is conducted on every single pixel, the two phase pixel units of the first column in each first phase-pixel unit tuple are applied with the same TX control signals as image pixel units in the same row, and the two phase pixel units of the second column in each second phase-pixel unit tuple are applied with the same TX control signals as image pixel units in the same row.

7. The pixel array according to claim 1, wherein the phase-pixel unit tuple pairs are spaced apart in the column-wise direction and the phase-pixel unit tuples are spaced apart in the row-wise direction.

8. The pixel array according to claim 7, comprising a plurality of repetitive units repeatedly arranged in the row-wise direction and the column-wise direction, wherein in each repetitive unit, phase-pixel unit tuples in adjacent columns are in different rows.

9. The pixel array according to claim 7, comprising a plurality of repetitive units repeatedly arranged in the row-wise direction and the column-wise direction, wherein in each repetitive unit, phase-pixel unit tuple pairs in adjacent rows are in different columns.

10. An image sensor comprising the pixel array of claim 1.
